(19) United States
(12) Patent Application Publication
(10) Pub. No.: US 2025/0183004 A1
(43) Pub. Date: Jun. 5, 2025

(54) PLASMA PROCESSING APPARATUS

(71) Applicant: Samsung Electronics Co., Ltd., Suwon-si (KR)

(72) Inventors: Hwasoo SEOK, Suwon-si (KR); Sungyong LIM, Suwon-si (KR); Yongwon CHO, Suwon-si (KR); Kyung-Sun KIM, Suwon-si (KR); Nam Kyun KIM, Suwon-si (KR); Sung-Yeol KIM, Suwon-si (KR); Donghyeon NA, Suwon-si (KR)

(73) Assignee: Samsung Electronics Co., Ltd., Suwon-si (KR)

(21) Appl. No.: 18/756,872

(22) Filed: Jun. 27, 2024

(30) Foreign Application Priority Data
Dec. 1, 2023 (KR) 10-2023-0172669

(51) Int. Cl. H01J 37/32

(52) U.S. Cl. CPC H01J 37/32146; H01J 2237/0473

(57) ABSTRACT

Provided is a plasma processing apparatus. The plasma processing apparatus includes a chamber where a wafer is configured to be mounted, a source power configured to provide a source voltage to generate a plasma in the chamber, a multi-level pulse circuit configured to generate a wafer voltage to accelerate ions in the plasma, and generate a pulse signal including a first pulse voltage, a second pulse voltage having a level lower than the first pulse voltage, and a third pulse voltage different from the first and second pulse voltages and having a level higher than the second pulse voltage, which are sequentially output, and an arbitrary voltage compensation circuit configured to provide a compensation voltage non-linearly changed to at least one of the first to third pulse voltages.

### CROSS-REFERENCE TO RELATED APPLICATION

This application claims priority to and the benefit of Korean Patent Application No. 10-2023-0172669 filed in the Korean Intellectual Property Office on Dec. 1, 2023, the entire contents of which are incorporated herein by reference.

### BACKGROUND OF THE INVENTION

The disclosure relates to a plasma processing apparatus.

A challenge in ultrafine semiconductor processing is to secure a high aspect ratio. There is a need for precise ion energy control technology to secure such a high aspect ratio, and a key part in ion energy control may be a pulse voltage generator of a bias power.

The precise ion control is possible only when a voltage on a wafer that is formed through an output voltage of the pulse voltage generator has an ideal rectangular waveform. A conventional pulse voltage generator may not sufficiently reflect a parasitic component in equipment or a non-linear ion charge accumulation of a load, and a rectangular wave formed by the voltage on the wafer may thus fail to have high perfection.

### SUMMARY

The disclosure attempts to provide a plasma processing apparatus with improved edge time performance of a voltage on a wafer.

The disclosure attempts to provide a plasma processing apparatus with an improved voltage droop phenomenon on a wafer.

The disclosure provides a plasma processing apparatus with a higher degree of freedom for controlling ions in a plasma.

According to various example embodiments, a plasma processing apparatus includes a chamber where a wafer is configured to be mounted, a source power configured to provide a source voltage to generate a plasma in the chamber, a multi-level pulse circuit configured to generate a wafer voltage to accelerate ions in the plasma, and generate a pulse signal including sequentially outputting a first pulse voltage, a second pulse voltage having a level lower than the first pulse voltage, and a third pulse voltage different from the first and second pulse voltages and having a level higher than the second pulse voltage, and an arbitrary voltage compensation circuit configured to provide a compensation voltage non-linearly changed to at least one of the first to third pulse voltages.

According to another embodiment, a plasma processing apparatus includes a chamber where a wafer is configured to be mounted, a source power configured to provide a source voltage to generate a plasma in the chamber, a multi-level pulse circuit configured to generate a wafer voltage to accelerate ions in the plasma, and generate a pulse signal including a rise edge where the voltage rises and a drop edge where the voltage drops, during a predetermined period, and an arbitrary voltage compensation circuit configured to provide a first boost voltage at the rise edge based on a boost period based on the predetermined period, provide a second boost voltage at the drop edge based on the boost period, and provide a process compensation voltage to the pulse signal after providing at least one of the first and second boost voltages.

According to still another embodiment, a plasma processing apparatus includes a chamber where a wafer is configured to be mounted, a gas injection unit configured to inject a process gas into the wafer, and including an upper electrode that is grounded, a supporter configured to support the wafer under the gas injection unit, and including a lower electrode, a source power electrically connected to the lower electrode, and configured to provide a source voltage to convert the process gas into plasma to generate plasma ions, and a bias power electrically connected to the lower electrode, configured to generate a plurality of pulse voltages including sequentially outputting a first pulse voltage, a second pulse voltage lower than the first pulse voltage, and a third pulse voltage different from the first and second pulse voltages and higher than the second pulse voltage, and perform a non-linear compensation operation for the second pulse voltages.

### BRIEF DESCRIPTION OF THE DRAWINGS

FIG. 1 is a schematic cross-sectional view of a plasma processing apparatus according to an embodiment.

FIG. 2 is a circuit diagram modeling the plasma processing apparatus according to an embodiment.

FIG. 3 is a block diagram showing a bias power according to an embodiment.

FIG. 4 is a view for describing a multi-level pulse circuit according to an embodiment.

FIG. 5 is a block diagram showing an arbitrary voltage compensation circuit according to an embodiment.

FIG. 6 is a view for describing a lookup table according to an embodiment.

FIGS. 7 to 9 are timing diagrams for describing a bias voltage of the bias power according to an embodiment.

FIG. 10 is a timing diagram for describing a wafer voltage according to an embodiment.

FIG. 11 is a graph for describing ion energy distribution based on the wafer voltage according to an embodiment.

FIG. 12 is a schematic cross-sectional view of a plasma processing apparatus according to an embodiment.

FIG. 13 is a timing diagram for describing a bias voltage of the bias power according to an embodiment.

FIG. 14 is a timing diagram for describing a wafer voltage according to an embodiment.

### DETAILED DESCRIPTION

Hereinafter, various example embodiments of the disclosure are described in detail with reference to the accompanying drawings for those skilled in the art to which the disclosure pertains to easily practice the disclosure. The disclosure may be implemented in various different forms and is not limited to the example embodiments provided herein.

A portion unrelated to the description is omitted in order to obviously describe the disclosure, and the same or similar components are denoted by the same reference numeral throughout the specification.

In addition, the size and thickness of each component shown in the accompanying drawings are arbitrarily shown for convenience of description, and therefore, the disclosure is not necessarily limited to contents shown in the drawings.

In addition, throughout the specification, unless described to the contrary, “including” any component will be understood to imply the inclusion of other elements rather than the exclusion of other elements.

In addition, even when explicitly recited in the claim, a specific number recited in a claim should not be construed as meaning that a limitation to the specific number does not exist in a claim where such citation does not exist. For example, for better understanding, a phrase “at least one” or “one or more” may be included in a subsequent dependent claim. However, use of such a phrase should not be understood as a limitation described by the article “one”, which is unclear, for the sake of one example.

Further, when an conventional expression such as “at least one of A, B, or C” is used, this expression will be well understood by those skilled in the art (that is, “a system including at least one of A, B, or C” indicates that the system includes A alone, B alone, C alone, A and B, A and C, B and C, and/or A, B and C all together, and is not limited to any one concept). Alternatively, letters and/or phrases in the description, the claim or the drawing that have two or more separate selectable terms should be considered as likely to include one, either one, or both the terms. For example, a phrase “A or B” should be understood as including a possibility “A”, or “B”, or “A and B”.

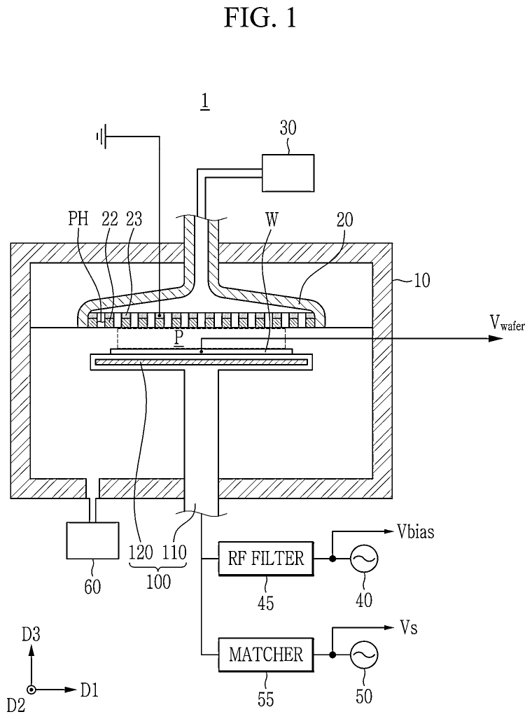

FIG. 1 is a schematic cross-sectional view of a plasma processing apparatus according to an embodiment. FIG. 1 shows a schematic cross-section of a plasma processing apparatus 1 based on a plane defined by a first direction D1 and a third direction D3.

The plasma processing apparatus 1 may include a chamber 10, a gas injection unit 20, a gas supply unit 30, a bias power 40, a radio frequency (RF) filter 45, a source power 50, a matcher circuit 55, and a gas exhaust unit 60, and may include a supporter 100. The plasma processing apparatus 1 may perform any one of ion beam etching, deposition of a plasma-based material film, and ion cleaning on a process target (e.g., a wafer).

Hereinafter, for convenience of description, the description focuses on various example embodiments where a wafer W, which is the process target, is mounted in the chamber 10, and the plasma processing apparatus 1 is a wafer processing apparatus for processing the wafer W. However, the example embodiments are examples, and do not limit the spirit of the disclosure in any way.

Although not shown, the plasma processing apparatus 1 may have a plurality of stations where processes are performed in the chamber 10. Each station may individually include the gas injection unit 20, the gas supply unit 30, the bias power 40, the RF filter 45, the source power 50, the matcher circuit 55, the gas exhaust unit 60, and the supporter 100. However, the disclosure is not limited thereto, and the plurality of stations may share some configurations.

The wafer W processed by the plasma processing apparatus 1 may be provided on the supporter 100. The wafer W may be, for example, a silicon wafer used in manufacturing a semiconductor integrated circuit (IC).

The chamber 10 may provide a space where the process progresses. The chamber 10 may have an upper wall, a side wall, and a lower wall. Although not shown, a passage through which the wafer W is brought in and out may be provided on one side of the chamber 10.

The gas injection unit 20 may include a plate 22 and an upper electrode 23. The gas injection unit 20 may be disposed above the supporter 100 in the third direction D3 so that the gas injection unit 20 faces the supporter 100 in the chamber 10. The gas injection unit 20 may be a component connected to the gas supply unit 30, and distributing a process gas supplied from the gas supply unit 30 to thus provide the same to an upper surface of the wafer W.

For example, the gas injection unit 20 may be a shower head, and the plate 22 may include a plurality of injection holes PH through which the process gas is injected. In some example embodiments, the upper electrode 23 may have the same shape as the plate 22, and may be aligned with the plate 22 to include a portion of the plurality of injection holes PH. In some example embodiments, the upper electrode may be grounded, and in other example embodiments, the upper electrode may be connected to the source power or the like.

In some example embodiments, the upper electrode 23 may be grounded, and a source voltage Vs in the form of a radio frequency (RF) signal may be supplied to a lower electrode 120 included in the supporter 100. Through the above structure, an electric field may be generated due to a voltage difference between the lower and upper parts of the wafer W. As a result, a plasma P may be generated in a process region where the process for the wafer W is performed. The process region may correspond to a region between the supporter 100 and the gas injection unit 20.

In addition, in the plasma processing apparatus 1 according to various example embodiments, at least a portion of the process gas may be converted into plasma. Therefore, the process gas may be activated to thus promote a reaction on the wafer W.

The plurality of injection holes PH may be arranged radially based on a central region of the gas injection unit 20. In the gas supply unit 30 according to various example embodiments, a diffusion plate may be further disposed to disperse the process gas.

The gas exhaust unit 60 may exhaust a reaction by-product and a residual gas in chamber 10 to the outside. The gas exhaust unit 60 may include a vacuum pump, and the above materials in the chamber 10 may be exhausted to the outside by a vacuum suction force generated by the vacuum pump. In some example embodiments, the arrangement position and arrangement number of the gas exhaust unit 60 may be changed in various ways.

The supporter 100 may be disposed in a lower region in the chamber 10. The supporter 100 may include a support unit 110 having an upper surface on which the wafer W is seated, and the lower electrode 120. As described above, the source voltage Vs may be supplied to the lower electrode 120 from the source power 50.

In some example embodiments, the support unit 110 may include a pillar part having a pillar shape and disposed in the center, and may have a circular upper surface on which the wafer W is seated. In some example embodiments, the pillar part may include a lifting pin at an upper end, and the wafer W may thus be lifted and brought in and out from outside the chamber 10 of FIG. 1.

The support unit 110 may be either a heater depending on the process performed in the plasma processing apparatus 1 or an electric static chuck (ESC) fixing and supporting the wafer W by an electrostatic force. The support unit 110 may include a heat conductor such as a heating wire inside, thus controlling a process temperature. The support unit 110 may include, for example, aluminum nitride (AlN), and is not limited thereto.

The lower electrode 120 may be connected to the bias power 40 or the source power 50. As described above, the lower electrode 120 according to an embodiment may receive the source voltage Vs in the form of the RF signal from the source power 50, and convert the process gas into a plasma to thus generate ions in plasma P.

In addition, the lower electrode 120 may receive a bias voltage Vbias to generate a wafer voltage Vwafer, which is a voltage of the wafer W that controls the ions in the plasma P. Hereinafter, the voltage of the wafer W is expressed as the wafer voltage Vwafer.

For convenience of description, the description is provided on an assumption that the plasma processing apparatus 1 uses a capacitively-coupled plasma chamber where the bias power 40 and the source power 50 are respectively connected to the lower electrode 120. However, the spirit of the disclosure is not limited thereto. In some example embodiments, the plasma processing apparatus 1 may use an inductively-coupled plasma chamber where the source voltage Vs, which is a continuous wave, is applied to the upper electrode 23, and the bias voltage Vbias is applied to the lower electrode 120.

The bias power 40 may generate the bias voltage Vbias. The wafer voltage Vwafer may be generated based on the bias voltage Vbias. The plasma processing apparatus 1 may accelerate ions in the plasma P in the chamber 10 through the wafer voltage Vwafer, and set an energy of the ions in the plasma P that reaches the wafer W. In some example embodiments, the plasma processing apparatus 1 may perform the process by accelerating ions in the plasma P in a direction opposite to the third direction D3.

A voltage level of the bias voltage Vbias may be variously adjusted by the bias power 40, and in some example embodiments, the bias voltage Vbias may be adjusted to at least three voltage levels. In some example embodiments, a frequency of the bias voltage Vbias may be different from a frequency of the source voltage Vs, and the plasma processing apparatus 1 may thus be a multi-frequency capacitively-coupled plasma etching device. In some example embodiments, the bias voltage Vbias may be provided in the form of the RF signal.

In addition, the RF filter 45 may be disposed at an output terminal of the bias power 40. In some example embodiments, the RF filter 45 may block the RF signal of a high frequency or a specific frequency range. The RF filter 45 may prevent or reduce the bias voltage Vbias of the bias power 40 from being affected by the source power 50.

A detailed description of a configuration of the bias power 40 is described below in the description of FIGS. 3 to 9.

The source power 50 may generate the source voltage Vs. Through the source voltage Vs, the plasma processing apparatus 1 may generate the plasma P in the process region. In some example embodiments, the source voltage Vs may be provided in the form of the RF signal.

In addition, the matcher circuit 55 may be disposed at an output terminal of the source power 50. In some example embodiments, the matcher circuit 55 may include a capacitor, a coil, or a combination thereof, and may perform an impedance matching operation for output of the source voltage Vs.

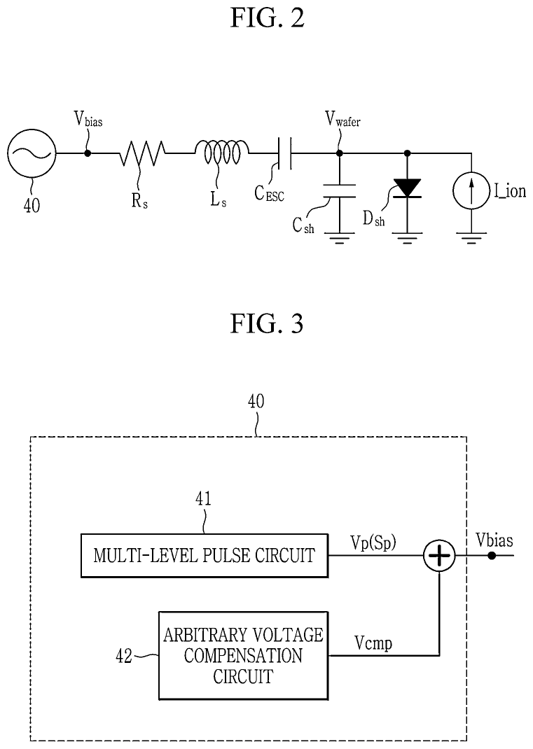

FIG. 2 is a circuit diagram modeling the plasma processing apparatus according to various example embodiments. FIG. 2 is a circuit diagram modeling the plasma processing apparatus 1 based on generation of the wafer voltage Vwafer.

Referring to FIGS. 1 and 2, the bias voltage Vbias may be generated by the bias power 40, and voltage-dropped due to a parasitic resistance Rs, a parasitic coil Ls, and a support capacitor Cesc to thus form the wafer voltage Vwafer on the wafer W.

Due to the parasitic resistance Rs and the parasitic coil Ls, a delay may occur in a change in the wafer voltage Vwafer due to a change in the bias voltage Vbias. For example, when the bias voltage Vbias rises from a first voltage to a second voltage at a specific time for a short rise edge time, the wafer voltage Vwafer may rise for a longer time than the rise edge time of the bias voltage Vbias due to the voltage rise of the bias voltage Vbias.

The parasitic resistance Rs and the parasitic coil Ls may be disposed in a transmission path of the bias voltage Vbias, may correspond to a component that affects the voltage drop, and for example, may correspond to the pillar part of the support unit 110. In some example embodiments, the support capacitor Cesc may correspond to an electronic stability control (ESC) in the supporter.

In addition, a sheath, which is a space of a positive ions and neutral atoms, formed between the plasma P and the supporter 100, may affect the formation of the wafer voltage Vwafer. The sheath may be modeled as a sheath capacitor Csh and a sheath diode Dsh. A capacitive load feature of the sheath in the chamber 10 may be modeled as the sheath capacitor Csh. In addition, a rectifying property of the sheath may be modeled as the sheath diode Dsh. It may be described that a sheath current, which is a type of Bohm current caused by a periodic collapse, flows through the sheath diode Dsh. The sheath diode Dsh may be provided to indicate a movement direction of the positive ion that is caused by a sheath collapse.

In addition, an ion current I_ion caused by accumulation of the ions in the plasma P during the process may affect the formation of the wafer voltage Vwafer. Therefore, the ion current I_ion may be modeled as a current source. However, the ion current I_ion according to various example embodiments may be non-linearly changed as the process (e.g., an etching process) progresses.

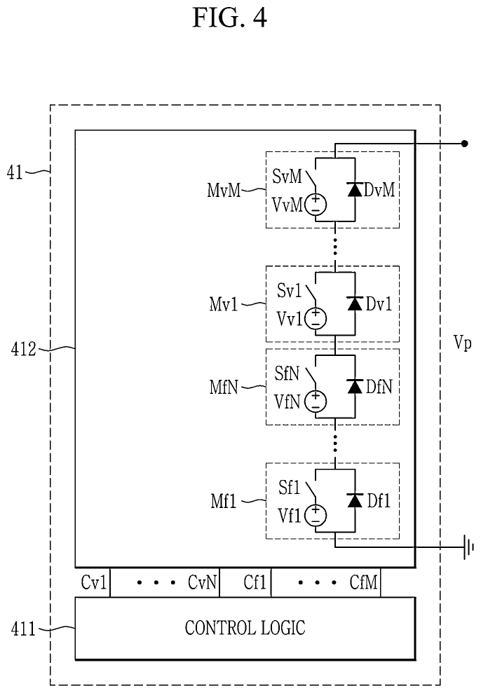

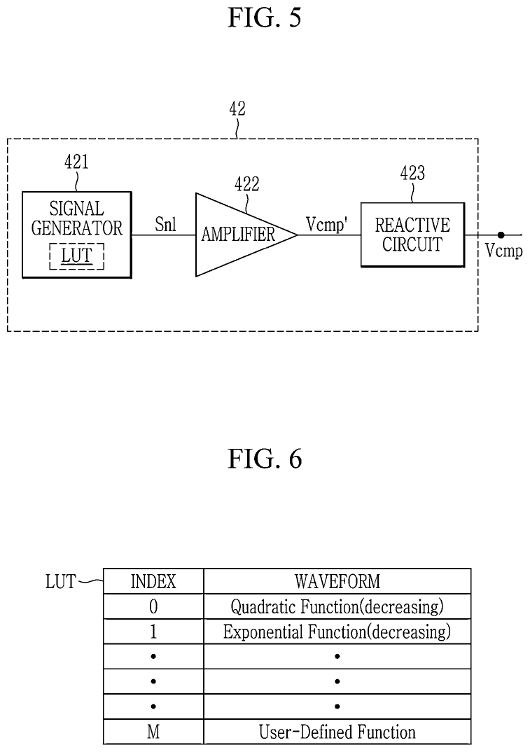

FIG. 3 is a block diagram showing the bias power according to various example embodiments. FIG. 4 is a view for describing a multi-level pulse circuit according to various example embodiments. FIG. 5 is a block diagram showing an arbitrary voltage compensation circuit according to various example embodiments. FIG. 6 is a view for describing a lookup table according to various example embodiments.

Referring to FIGS. 1 and 3 to 6, the bias power 40 may include a multi-level pulse circuit 41 and an arbitrary voltage compensation circuit 42.

The bias power 40 may generate the bias voltage Vbias by adding a pulse voltage Vp output from the multi-level pulse circuit 41 and a compensation voltage Vcomp for the pulse voltage Vp that is output from the arbitrary voltage compensation circuit 42 to each other.

The generated bias voltage Vbias may generate the wafer voltage Vwafer close to an ideal rectangular waveform. In some example embodiments, the wafer voltage may be generated through the pulse voltage Vp, and through compensation voltage Vcomp, the wafer voltage Vwafer may have a waveform close to the ideal rectangular waveform.

The multi-level pulse circuit 41 may include control logic 411 and a pulse voltage generation circuit 412. The multi-level pulse circuit 41 may output at least three voltage levels. In addition, the multi-level pulse circuit 41 may have a voltage rise based on a rise edge based on a bias period based on the frequency of the bias voltage Vbias, and may output the pulse voltage Vp in the form of a pulse signal Sp having a voltage drop based on a drop edge. In some example embodiments, the multi-level pulse circuit 41 may output the pulse voltage having two voltage levels based on a set duty ratio in one bias period.

The control logic 411 may output a plurality of control signals Cv1 to CvN and Cf1 to CfM to thus control a plurality of variable voltage modules Mv1 to MvM and a plurality of fixed voltage modules Mf1 to MfN, included in the pulse voltage generation circuit 412.

The control logic 411 may control an operation of the pulse voltage generation circuit 412 through the plurality of control signals Cv1 to CvN and Cf1 to CfM. The control logic 411 may be a computing device such as a workstation computer, a desktop computer, a laptop computer, or a tablet computer. However, example embodiments are not limited thereto. Each control logic 411 may include separate hardware or separate software included in one hardware. The control logic 411 may be a simple controller, a complex processor such as a microprocessor, a graphic processing unit (GPU), or a graphic processing unit (GPU), a processor configured by software, dedicated hardware, or firmware. However, example embodiments are not limited thereto. For example, the control logic 411 may be implemented by a general-purpose computer or application-specific hardware such as a digital signal processor (DSP), a field programmable gate array (FPGA), or an application specific integrated circuit (ASIC).

In some example embodiments, an operation of the control logic 411 may be implemented by instructions stored on a machine-readable medium that may be read and executed by one or more processors. Here, the machine-readable medium may include any mechanism for storing and/or transmitting information in a form readable by a machine (e.g., the computing device). For example, the machine-readable medium may include a read only memory (ROM), a random access memory (RAM), a magnetic disk storage medium, an optical storage medium, a flash memory device, a radio signal (e.g., a carrier wave, an infrared signal, or a digital signal) of electrical, optical, acoustic or another type, or any other signal. However, example embodiments are not limited thereto.

The operation of the control logic 411 described above, or its operation for performing an arbitrary process described below, may also be implemented by firmware, software, routines, and instructions. For example, the control logic 411 may be implemented by software that performs a function such as determining the plurality of control signals Cv1 to CvN and Cf1 to CfM. However, this configuration is provided for convenience of description, and it should be understood that the operation of the control logic 411 described above may result from the computing device, the processor, the controller, or another device executing the firmware, the software, the routines, the instructions, or the like.

The pulse voltage generation circuit 412 may output the pulse voltage Vp through the plurality of variable voltage modules Mv1 to MvM and the plurality of fixed voltage modules Mf1 to MfN. The plurality of variable voltage modules Mv1 to MvM may include the first to M variable voltage modules Mv1 to MvM. The plurality of fixed voltage modules Mf1 to MfM may include the first to M fixed voltage modules Mf1 to MfM.

In some example embodiments, the first to M variable voltage modules Mv1 to MvM and the first to M fixed voltage modules Mf1 to MfM may be connected in series with each other between the output terminal and a ground terminal. In some example embodiments, the pulse voltage Vp may be generated by adding voltages output from the first to M variable voltage modules Mv1 to MvM and the first to M fixed voltage modules Mf1 to MfM to each other, selected by the plurality of control signals Cv1 to CvN and Cf1 to CfM.

For easy description, the first to M variable voltage modules Mv1 to MvM are described focusing on the first variable voltage module Mv1. It is obvious that the description of each configuration of the first to M variable voltage modules Mv1 to MvM is replaced by the description of a configuration of the first variable voltage module Mv1.

The first variable voltage module Mv1 may include a first variable voltage source Vv1, a first variable voltage switch SV1, and a first variable module diode Dv1.

The first variable voltage source Vv1 may provide a variable voltage having a voltage magnitude changed based on its operation. In some example embodiments, the variable voltage may have a smaller voltage magnitude than each fixed voltage output from the first to M fixed voltage modules Mf1 to MfM. The pulse voltage Vp may be precisely changed through the magnitude of the first variable voltage source Vv1 as described above. In some example embodiments, the magnitude of the variable voltage output from the first variable voltage source Vv1 may be the same as or different from that of each variable voltage output from the other of the plurality of variable voltage modules Vv1 to VvM.

The first variable voltage switch SV1 may be connected in series with the first variable voltage source Vv1, may be selected by the first variable control signal Cv1, and may be short-circuited when selected to output the variable voltage of the first variable voltage source Vv1. The first variable module diode Dv1 may be connected in parallel with the first variable voltage switch SV1 and the first variable voltage source Vv1, which are connected in series with each other, and may be operated as a diode when the first variable voltage switch SV1 is not selected by the first variable control signal Cv1. Through the operation of the first variable voltage module diode Dv1, the pulse voltage generation circuit 412 may output the pulse voltage Vp even when the first variable voltage module Mv1 outputs no voltage.

For easy description, the first to N variable voltage modules Mf1 to MfN are described focusing on the first fixed voltage module Mf1. It is obvious that the description of each configuration of the first to N variable voltage modules Mf1 to MfM is replaced by the description of a configuration of the first fixed voltage module Mf1.

The first fixed voltage module Mf1 may include a first fixed voltage source Vf1, a first fixed voltage switch Sf1, and a first fixed module diode Df1.

The first fixed voltage source Vf1 may provide a fixed voltage having a voltage magnitude fixed based on its operation. In some example embodiments, the magnitude of the fixed voltage output from the first fixed voltage source Vf1 may be the same as or different from that of each fixed voltage output from the other of the plurality of fixed voltage modules Vf1 to VfN.

The first fixed voltage switch Sf1 may be connected in series with the first fixed voltage source Vf1, may be selected by the first fixed control signal Cf1, and may be short-circuited when selected to output the fixed voltage of the first fixed voltage source Vf1. The first fixed module diode Df1 may be connected in parallel with the first fixed voltage switch Sf1 and the first fixed voltage source Vf1, which are connected in series with each other, and may be operated as the diode when the first fixed voltage switch Sf1 is not selected by the first fixed control signal Cf1. Through the operation of the first fixed module diode Df1, the pulse voltage generation circuit 412 may output the pulse voltage Vp even when the first fixed voltage module Mf1 outputs no voltage.

The pulse voltage generation circuit 412 in the disclosure may output the pulse voltage Vp with at least three voltage levels by including individual voltage modules connected in series with each other and using a selection of the individual voltage module and a combination thereof, rather than including a circuit structure that individually outputs the pulse voltage and has components connected in parallel with each other. Through the structure and operation of the control logic 411 and the pulse voltage generation circuit 412, a degree of freedom may rise in the process of the plasma processing apparatus 1 through the pulse voltage Vp, and an area overhead for the pulse voltage generation circuit 412 may be improved.

The arbitrary voltage compensation circuit 42 may include a signal generator 421, an amplifier 422, and a reactive circuit 423. The arbitrary voltage compensation circuit 42 may output the compensation voltage Vcomp for the pulse voltage Vp. The arbitrary voltage compensation circuit 42 may generate a positive boost voltage in synchronization with a rise edge of the pulse voltage Vp during one bias period to output the compensation voltage Vcomp, and may generate a negative boost voltage in synchronization with a drop edge of the pulse voltage Vp to output the compensation voltage Vcomp.

The arbitrary voltage compensation circuit 42 may generate the process compensation voltage after generating the positive boost voltage or generating the negative boost voltage during one bias period to output the compensation voltage Vcomp. In some example embodiments, the process compensation voltage may be provided for compensation for the ion current I_ion of FIG. 2 as the plasma processing apparatus 1 performs the process.

The signal generator 421 may determine a waveform of the compensation voltage Vcomp, and output a non-linear signal Snl based on the determined waveform. The non-linear signal Snl may include each waveform of the positive boost voltage, the negative boost voltage, and the process compensation voltage.

The signal generator 421 may include a look-up table LUT including waveform information of the process compensation voltage. The signal generator 421 may output the non-linear signal Snl based on the look-up table LUT. In some example embodiments, the waveform of the process compensation voltage may be non-linearly changed.

Referring to FIG. 6 as an example, the look-up table LUT may store the waveform information of M+1 number of process compensation voltages corresponding to each index. The look-up table LUT may store quadratic curve function information in which a signal level is lower over time by corresponding to an index zero, may store exponential function information in which the signal level is lower over time by corresponding to an index 1, and may store user-defined waveform information corresponding to an index M. The waveform information described above is an example provided for easy description, and the spirit of the disclosure is not limited thereto.

The amplifier 422 may receive and amplify the non-linear signal Snl, output a preliminary compensation voltage Vcomp′, and provide the same to the reactive circuit. The amplifier 422 may include a voltage amplifier, a transresistance amplifier, a single-stage amplifier, a multi-stage amplifier, or the like, however, example embodiments are not limited thereto.

The reactive circuit 423 may include the capacitor, the coil, or a combination thereof. In some example embodiments, the reactive circuit 423 may be operated as an isolator and receive the preliminary compensation voltage Vcomp′ to output the same as the compensation voltage Vcomp. In some example embodiments, the reactive circuit 423 may include a transformer coil when the reactive circuit 423 is operated as the isolator. In some example embodiments, the reactive circuit 423 may be operated as an RF matcher and perform an impedance matching operation for the preliminary compensation voltage Vcomp′, and is not limited thereto.

The arbitrary voltage compensation circuit 42 may actively reflect the structure and electrical feature of the plasma processing apparatus 1, and may perform a non-linear compensation operation for the pulse voltage Vp as described above. Through the compensation operation, the wafer voltage Vwafer of the wafer W on which the process is performed may have a waveform close to the ideal rectangular waveform.

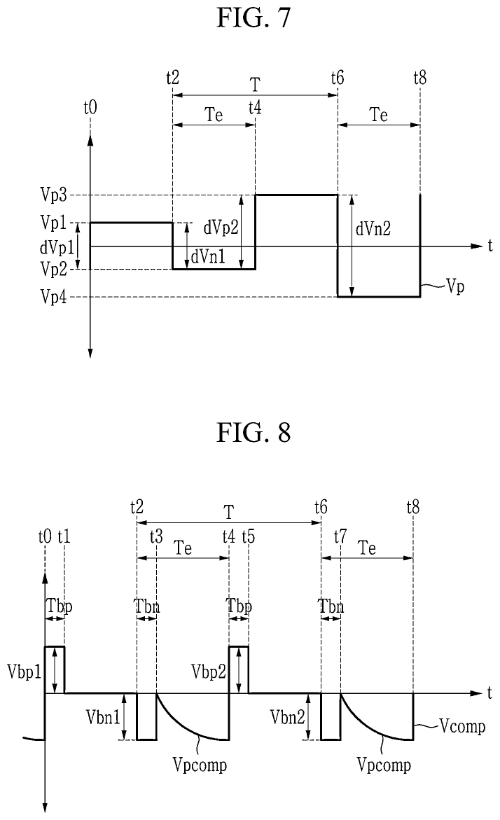

FIGS. 7 to 9 are timing diagrams for describing the bias voltage of the bias power according to various example embodiments. FIG. 10 is a timing diagram for describing the wafer voltage according to various example embodiments.

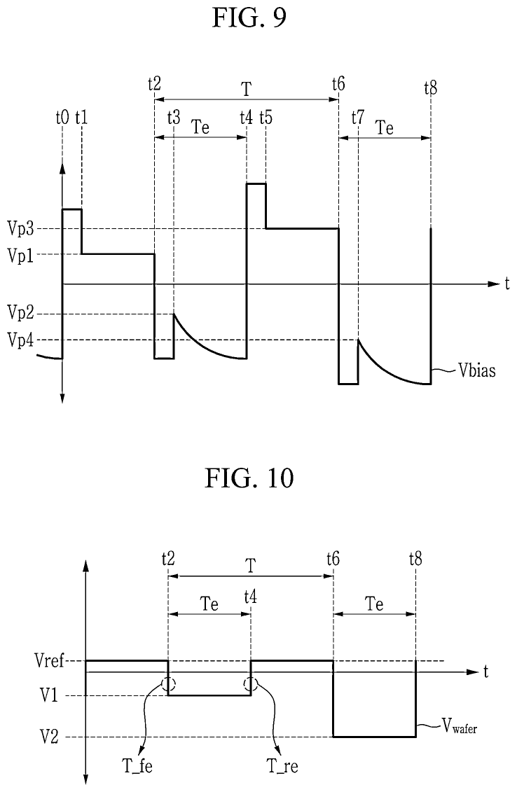

FIG. 7 is a timing diagram for the pulse voltage Vp output from the multi-level pulse circuit 41, FIG. 8 is a timing diagram for the compensation voltage Vcomp output from the arbitrary voltage compensation circuit 42, FIG. 9 shows the bias voltage Vbias acquired by adding the pulse voltage Vp and the compensation voltage Vcomp to each other, and FIG. 10 is a timing diagram for the wafer voltage Vwafer generated through the bias voltage Vbias.

Referring to FIGS. 1 and 3 to 10, a time point to may be a rise edge time point of the pulse voltage Vp. At the time point t0, the pulse voltage Vp may rise by a first voltage rise range dVp1. The pulse voltage Vp may rise by the first voltage rise range dVp1 to have the voltage magnitude of a level of a first pulse voltage Vp1. In addition, the compensation voltage Vcomp may be in synchronization with the rise edge of the pulse voltage Vp at the time point t0 to rise by a first positive boost voltage Vbp1. Therefore, at the time point to, the bias voltage Vbias may rise by the sum of the first voltage rise range dVp1 and the first positive boost voltage Vbp1.

In some example embodiments, a ratio of a magnitude of the first positive boost voltage Vbp1 and the first voltage rise range dVp1 may be within zero to 1, and preferably 0.1 to 0.3. A ratio of a magnitude of a second positive boost voltage Vbp2 and a second voltage rise range dVp2, a ratio of a magnitude of a first negative boost voltage Vbn1 and a first voltage drop range dVn1, and a ratio of a magnitude of a second negative boost voltage Vbn2 and a second voltage drop range dVn2 may then also be within zero to 1, preferably 0.1 to 0.3.

A period from the time point to to a time point t1 may be a rise boost period Tbp in which the first positive boost voltage Vbp1 is maintained. During the period from the time point to to the time point t1, the pulse voltage Vp may maintain the first pulse voltage Vp1. The compensation voltage Vcomp may maintain a level of the first positive boost voltage Vbp1. Likewise, the bias voltage Vbias may maintain its voltage level at the time point to.

The time point t1 may be a drop edge time point of the compensation voltage Vcomp. At the time point t1, the compensation voltage Vcomp may drop by the first positive boost voltage Vbp1. Therefore, at the time point to, the bias voltage Vbias may drop by the first positive boost voltage Vbp1.

During a period from the time point t1 to a time point t2, the pulse voltage Vp may maintain the first pulse voltage Vp1, and the compensation voltage Vcomp may not be generated. Likewise, the bias voltage Vbias may maintain its voltage level at the time point t1.

The time point t2 may be a drop edge time point of the pulse voltage Vp. At the time point t2, the pulse voltage Vp may drop by the first voltage drop range dVn1. The pulse voltage Vp may drop by the first voltage drop range dVn1 to have the voltage magnitude of a level of a second pulse voltage Vp2. In some example embodiments, the voltage level of the second pulse voltage Vp2 and that of the first pulse voltage Vp1 may be different from each other. In addition, the compensation voltage Vcomp may be in synchronization with the drop edge of the pulse voltage Vp at the time point t2 to drop by a first negative boost voltage Vbn1. Therefore, at the time point t2, the bias voltage Vbias may drop by the sum of the first voltage drop range dVn1 and the first negative boost voltage Vbn1.

A period from the time point t2 to a time point t4, which is the rise edge time point of the pulse voltage Vp, may be defined as an etching period Te, which is a process performance period of the plasma processing apparatus 1. In some example embodiments, the process performance period may be determined in consideration of a polarity of the ions in the plasma P, an acceleration direction of the ions in the plasma P when performing the process, and the voltages applied to the upper electrode 23 and the lower electrode 120. Referring to FIG. 1 as an example, assuming that the upper electrode 23 is grounded, the bias voltage Vbias in the form of the RF signal is applied to the lower electrode 120, the ions in the plasma P are positive ions, and a process performance direction is opposite to the third direction D3, the process (e.g., etching process) of the plasma processing apparatus 1 may be performed during the period from the time point t2, which is the drop edge time point of the pulse voltage Vp, to the time point t4, which is the rise edge time point of the pulse voltage Vp.

A period from the time point t2 to a time point t3 may be a drop boost period Tbn in which the first negative boost voltage Vbn1 is maintained. During the period from the time point t2 to the time point t3, the pulse voltage Vp may maintain the second pulse voltage Vp2. The compensation voltage Vcomp may maintain a level of the first negative boost voltage Vbn1. Likewise, the bias voltage Vbias may maintain its voltage level at the time point t2.

The time point t3 may be a rise edge time point of the compensation voltage Vcomp. At the time point t3, the compensation voltage Vcomp may rise by the first negative boost voltage Vbn1. Therefore, at the time point t3, the bias voltage Vbias may rise by the first negative boost voltage Vbn1.

During a period from the time point t3 to a time point t4, the pulse voltage Vp may maintain the second pulse voltage Vp2, and the compensation voltage Vcomp may be changed by a process compensation voltage Vpcomp. Referring to FIG. 8 as an example, the compensation voltage Vcomp may be changed in the form of a quadratic curve which is reduced over time, is not limited thereto, and may be non-linearly changed in various ways. In some example embodiments, the compensation voltage Vcomp may drop in at least a portion of the period from the time point t3 to the time point t4. Likewise, the bias voltage Vbias may be changed by the process compensation voltage Vpcomp during the period from the time point t3 to the time point t4.

During the etching period Te, the compensation operation may be performed for the second pulse voltage Vp2 based on the first negative boost voltage Vbn1 and the process compensation voltage Vpcomp.

The time point t4 may be the rise edge time point of the pulse voltage Vp. At the time point t4, the pulse voltage Vp may rise by the second voltage rise range dVp2. The pulse voltage Vp may rise by the second voltage rise range dVp2 to have the voltage magnitude of a level of a third pulse voltage Vp3. In some example embodiments, the voltage level of the third pulse voltage Vp3 may be different from those of the first and second pulse voltages Vp1 and Vp2. In addition, the compensation voltage Vcomp may be in synchronization with the rise edge of the pulse voltage Vp at the time point t4 to rise by the second positive boost voltage Vbp2. Therefore, at the time point t4, the bias voltage Vbias may rise by the sum of the second voltage rise range dVp2 and the second positive boost voltage Vbp2.

A period from the time point t4 to a time point t5 may be the rise boost period Tbp in which the second positive boost voltage Vbp2 is maintained. During the period from the time point t4 to the time point t5, the pulse voltage Vp may maintain the third pulse voltage Vp3. The compensation voltage Vcomp may maintain a level of the second positive boost voltage Vbp2. Likewise, the bias voltage Vbias may maintain its voltage level at the time point t4.

The time point t5 may be the drop edge time point of the compensation voltage Vcomp. At the time point t5, the compensation voltage Vcomp may drop by the second positive boost voltage Vbp2. Therefore, at the time point t5, the bias voltage Vbias may drop by the second positive boost voltage Vbp2.

During a period from the time point t5 to a time point t6, the pulse voltage Vp may maintain the third pulse voltage Vp3, and the compensation voltage Vcomp may not be generated. Likewise, the bias voltage Vbias may maintain its voltage level at the time point t5.

A period from the time point t2 to the time point t6 may be a period between the drop edges and including one drop edge and one rise edge, and the period from the time point t2 to the time point t6 may be defined as a bias period T corresponding to the frequency of the bias voltage Vbias.

In some example embodiments, a time ratio of the rise boost period Tbp and the bias period T may be zero to 0.15, preferably 0.05 to 0.15. Likewise, in some example embodiments, a time ratio of the drop boost period Tbn and the bias period T may be zero to 0.15, preferably 0.05 to 0.15. In addition, although not shown, the bias period T may be a period from the rise edge time points t0 to t4 and including one rise edge and one drop edge.

The time point t6 may be the drop edge time point of the pulse voltage Vp. At the time point t6, the pulse voltage Vp may drop by the second voltage drop range dVn2. The pulse voltage Vp may drop by the second voltage drop range dVn2 to have the voltage magnitude of a level of a fourth pulse voltage Vp4. In some example embodiments, the voltage level of the fourth pulse voltage Vp4 may be different from those of the first to third pulse voltages Vp1 to Vp3. In addition, the compensation voltage Vcomp may be in synchronization with the drop edge of the pulse voltage Vp at the time point t6 to drop by the second negative boost voltage Vbn2. Therefore, at the time point t6, the bias voltage Vbias may drop by the sum of the second voltage drop range dVn2 and the second negative boost voltage Vbn2.

A period from the time point t6 to a time point t7 may be the drop boost period Tbn in which the second negative boost voltage Vbn2 is maintained. During the period from the time point t6 to the time point t7, the pulse voltage Vp may maintain the fourth pulse voltage Vp4. The compensation voltage Vcomp may maintain the level of the first negative boost voltage Vbn1. Likewise, the bias voltage Vbias may maintain its voltage level at the time point t6.

The time point t7 may be the rise edge time point of the compensation voltage Vcomp. At the time point t7, the compensation voltage Vcomp may rise by the second negative boost voltage Vbn2. Therefore, at the time point t7, the bias voltage Vbias may rise by the second negative boost voltage Vbn2.

During a period from the time point t7 to a time point t8, the pulse voltage Vp may maintain the fourth pulse voltage Vp4, and the compensation voltage Vcomp may be changed by the process compensation voltage Vpcomp. Referring to FIG. 8 as an example, the compensation voltage Vcomp may be changed in the form of the quadratic curve, which is reduced over time, is not limited thereto, and may be non-linearly changed in various ways. In some example embodiments, the compensation voltage Vcomp may drop in at least a portion of the period from the time point t7 to the time point t8. Likewise, the bias voltage Vbias may be changed by the process compensation voltage Vpcomp during the period from the time point t7 to the time point t8. During the etching period Te from the time point t7 to the time point t8, the compensation operation may be performed for the fourth pulse voltage Vp4 based on the second negative boost voltage Vbn2 and the process compensation voltage Vpcomp.

FIG. 8 shows that the pulse voltage Vp is output as the first to fourth pulse voltages Vp1 to Vp4 with the different voltage levels. However, the pulse voltage Vp may be output as two voltage levels based on the operation of the plasma processing apparatus 1.

Referring to FIG. 10 together, the wafer voltage Vwafer may be changed by the bias voltage Vbias. The time point t2, which is the drop edge time point of the bias voltage Vbias, may be a drop edge of the wafer voltage Vwafer. At the time point t2, through the first negative boost voltage Vbn1 of the compensation voltage Vcomp, a delay caused by the parasitic resistance Rs and parasitic coil Ls of FIG. 2 may be prevented or reduced, and performance of a drop edge transition time T_fe of the wafer voltage Vwafer may be improved.

The wafer voltage Vwafer may maintain a first voltage V1 without a droop phenomenon from the time point t2, which is the etching period Te, to the time point t4. Likewise, the wafer voltage Vwafer may maintain a second voltage V2 without the droop phenomenon from the time point t6 to the time point t8, which is the etching period Te. Compensation operation performance for the non-linear ion current I_ion of FIG. 2 may be improved by performing the compensation operation based on the process compensation voltage Vpcomp of the disclosure during the etching period Te.

The time point t4, which is the rise edge time point of the bias voltage Vbias, may be a rise edge of the wafer voltage Vwafer. At the time point t4, through the second positive boost voltage Vbp2 of the compensation voltage Vcomp, the delay caused by the parasitic resistance Rs and parasitic coil Ls of FIG. 2 may be prevented or reduced, and performance of a rise edge transition time T_re of the wafer voltage Vwafer may be improved.

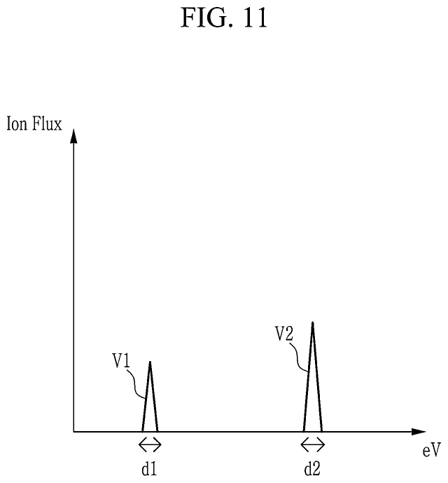

FIG. 11 is a graph for describing ion energy distribution based on the wafer voltage according to an embodiment. FIG. 11 shows an ion energy distribution function (IEDF) based on the wafer voltage Vwafer.

Referring to FIGS. 1, 10, and 11, through the bias voltage Vbias of the bias power 40, the wafer voltage Vwafer may have the waveform close to an ideal rectangular waveform during the etching period Te, which is the process performance period.

The wafer voltage Vwafer may maintain the first voltage V1 without any delay or droop phenomenon in the voltage generation from the time point t2, which is the etching period Te, to the time point t4, and maintain the second voltage V2 without any delay or droop phenomenon in the voltage generation from the time point t6, which is the etching period Te, to the time point t8.

Through the improved rectangular waveform of the wafer voltage Vwafer, the plasma processing apparatus 1 may narrowly form a first ion energy distribution d1 for the ions in the plasma P by the first voltage V1 and second ion energy distribution d2 for the ions in the plasma P by the second voltage V2. Through the improved rectangular waveform of the wafer voltage Vwafer, the plasma processing apparatus 1 may enable precise ion control and secure a high aspect ratio for an ultrafine process.

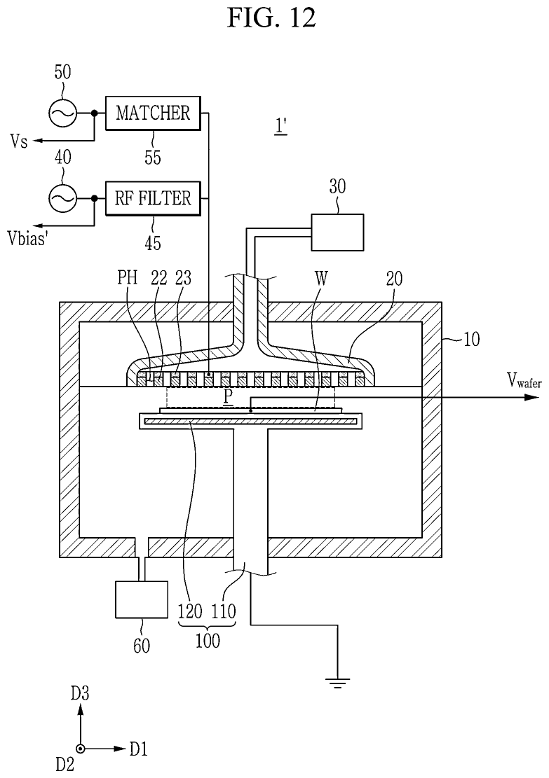

FIG. 12 is a schematic cross-sectional view of a plasma processing apparatus according to an embodiment. A plasma processing apparatus 1′ in FIG. 12 may correspond to the plasma processing apparatus 1 in FIG. 1, and for easy description, the description focuses on a difference between their configurations.

Referring to FIGS. 1 and 12, the lower electrode 120 may be grounded, and the bias power 40 and the source power 50 may be connected to the upper electrode 23.

The source power 50 may provide the source voltage Vs in the form of the RF signal to generate the plasma P on the upper electrode 23. The bias power 40 may provide a bias voltage Vbias' to the upper electrode 23 to accelerate the ions in the plasma P.

Therefore, assuming that the lower electrode 120 is grounded, the bias voltage Vbias' in the form of the RF signal is applied to the upper electrode 23, the ions in the plasma P are the positive ions, and the process performance direction is opposite to the third direction D3, a process (e.g., etching process) of the plasma processing apparatus 1′ may be performed during the period from the rise edge time point to drop edge time point of the pulse voltage Vp.

Like the plasma processing apparatus 1 in FIG. 1, the matcher circuit 55 may be disposed at the output terminal of the source power 50 and may perform the impedance matching operation of the source voltage Vs. In addition, the RF filter 45 may be disposed at the output terminal of the bias power 40, thus preventing or reducing the bias voltage Vbias' of the bias power 40 from being affected by the source power 50.

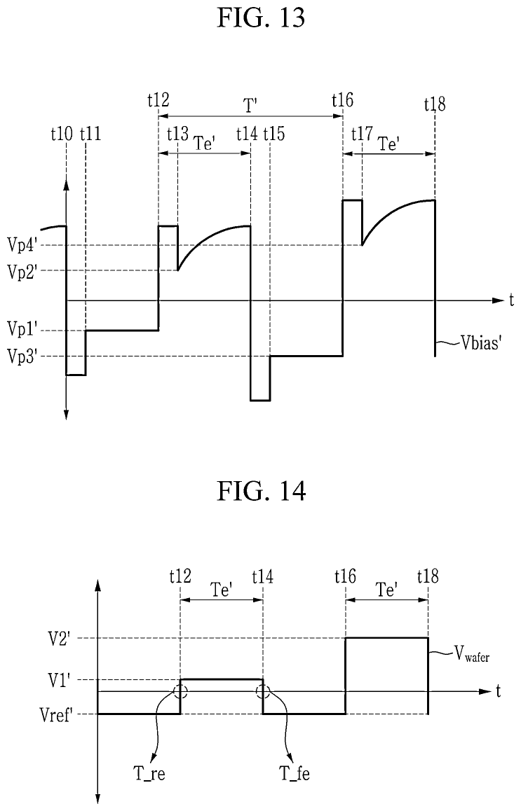

FIG. 13 is a timing diagram for describing the bias voltage of the bias power according to various example embodiments. FIG. 14 is a timing diagram for describing a wafer voltage according to various example embodiments.

FIGS. 13 and 14 are timing diagrams for describing an operation of the plasma processing apparatus 1′ of FIG. 12.

Referring to FIGS. 3 and 12 to 14, a time point t10 may be the drop edge time point of the pulse voltage Vp. At the time point t10, the pulse voltage Vp may be a first pulse voltage Vp1′. In addition, the compensation voltage Vcomp may be in synchronization with the drop edge of the pulse voltage Vp at the time point t10 to drop by the negative boost voltage. Therefore, at the time point t10, the bias voltage Vbias' may drop by the sum of the drop range of the pulse voltage Vp and the negative boost voltage.

A period from the time point t10 to a time point t11 may be the drop boost period in which the negative boost voltage is maintained. During the period from the time point t10 to the time point t11, the pulse voltage Vp may drop and its voltage level may be changed to the first pulse voltage Vp1′. The compensation voltage Vcomp may maintain a negative boost voltage level. Likewise, the bias voltage Vbias' may maintain its voltage level at the time point t10.

The time point t11 may be the rise edge time point of the compensation voltage Vcomp. At the time point t11, the compensation voltage Vcomp may rise by the negative boost voltage. Therefore, at the time point t11, the bias voltage Vbias' may rise by the negative boost voltage.

During a period from the time point t11 to a time point t12, the pulse voltage Vp may maintain the first pulse voltage Vp′, and the compensation voltage Vcomp may not be generated. Likewise, the bias voltage Vbias' may maintain its voltage level at the time point t11.

The time point t12 may be the rise edge time point of the pulse voltage Vp. At the time point t12, the pulse voltage Vp may rise and its voltage level may be changed to a second pulse voltage Vp2′. In some example embodiments, a voltage level of the second pulse voltage Vp2′ and that of the first pulse voltage Vp1′ may be different from each other. In addition, the compensation voltage Vcomp may be in synchronization with the rise edge of the pulse voltage Vp at the time point t12 to rise by the positive boost voltage. Therefore, at the time point t12, the bias voltage Vbias' may rise by the sum of the rise range of the pulse voltage Vp and the positive boost voltage.

A period from the time point t12 to a time point t13 may be the rise boost period in which the positive boost voltage is maintained. During the period from the time point t12 to the time point t13, the pulse voltage Vp may maintain the second pulse voltage Vp2′. The compensation voltage Vcomp may maintain a positive boost voltage level. Likewise, the bias voltage Vbias' may maintain its voltage level at the time point t12.

The time point t13 may be the drop edge time point of the compensation voltage Vcomp. At the time point t13, the compensation voltage Vcomp may drop by the positive boost voltage. Therefore, at the time point t13, the bias voltage Vbias' may drop by the positive boost voltage.

During a period from the time point t13 to a time point t14, the pulse voltage Vp may maintain the second pulse voltage Vp2′, and the compensation voltage Vcomp may be changed by the process compensation voltage. Likewise, the bias voltage Vbias' may be changed by the process compensation voltage during the period from the time point t13 to the time point t14.

During an etching period Te′, the compensation operation may be performed for the second pulse voltage Vp2′ based on the positive boost voltage and the process compensation voltage. In some example embodiments, the compensation voltage Vcomp may output the negative boost voltage after the compensation operation is performed by the process compensation voltage.

The time point t14 may be the drop edge time point of the pulse voltage Vp. At the time point t14, the pulse voltage Vp may drop and its voltage level may be changed to a third pulse voltage Vp3′. In some example embodiments, the voltage level of the third pulse voltage Vp3′ may be different from those of the first and second pulse voltages Vp1′ and Vp2′. In addition, the compensation voltage Vcomp may be in synchronization with the drop edge of the pulse voltage Vp at the time point t14 to drop by the negative boost voltage. Therefore, at the time point t14, the bias voltage Vbias' may drop by the sum of the drop range of the pulse voltage Vp and the negative boost voltage.

A period from the time point t14 to a time point t15 may be the drop boost period in which the negative boost voltage is maintained. During the period from the time point t14 to the time point t15, the pulse voltage Vp may maintain the third pulse voltage Vp3′. The compensation voltage Vcomp may maintain the level of the negative boost voltage. Likewise, the bias voltage Vbias' may maintain its voltage level at the time point t14.

The time point t15 may be the rise edge time point of the compensation voltage Vcomp. At the time point t15, the compensation voltage Vcomp may rise by the negative boost voltage. Therefore, at the time point t15, the bias voltage Vbias' may rise by the negative boost voltage.

During a period from the time point t15 to a time point t16, the pulse voltage Vp may maintain the third pulse voltage Vp3′, and the compensation voltage Vcomp may not be generated. Likewise, the bias voltage Vbias' may maintain its voltage level at the time point t15.

A period from the time point t16 to the time point t17 may be a period between the drop edges and including one drop edge and one rise edge, and the period from the time point t12 to the time point t16 may be defined as a bias period T′ corresponding to a frequency of the bias voltage Vbias′.

In addition, although not shown, the bias period T′ may be a period from the rise edge time points t10 to t14 and including one rise edge and one drop edge.

The time point t16 may be the rise edge time point of the pulse voltage Vp. At the time point t16, the pulse voltage Vp may rise and its voltage level may be changed to a fourth pulse voltage Vp4′. In some example embodiments, the voltage level of the fourth pulse voltage Vp4′ may be different from those of the first to third pulse voltages Vp1′ to Vp3′. In addition, the compensation voltage Vcomp may be in synchronization with the rise edge of the pulse voltage Vp at the time point t16 to rise by the positive boost voltage. Therefore, at the time point t16, the bias voltage Vbias' may rise by the sum of the rise range of the pulse voltage Vp and the positive boost voltage.

A period from the time point t16 to a time point t17 may be the rise boost period in which the positive boost voltage is maintained. During the period from the time point t16 to the time point t17, the pulse voltage Vp may maintain the fourth pulse voltage Vp4′. The compensation voltage Vcomp may maintain the level of the positive boost voltage. Likewise, the bias voltage Vbias' may maintain its voltage level at the time point t16.

The time point t17 may be the drop edge time point of the compensation voltage Vcomp. At the time point t17, the compensation voltage Vcomp may drop by the positive boost voltage. Therefore, at the time point t17, the bias voltage Vbias' may drop by the positive boost voltage.

During a period from the time point t17 to a time point t18, the pulse voltage Vp may maintain the fourth pulse voltage Vp4′, and the compensation voltage Vcomp may be changed by the process compensation voltage. Likewise, the bias voltage Vbias' may be changed by the process compensation voltage during the period from the time point t17 to the time point t18. Unlike the compensation voltage Vcomp dropping in the period from the time point t7 to the time point t8 in FIGS. 8 and 9, the compensation voltage Vcomp may rise during the period from the time point t17 to the time point t18. During the etching period Te′, the compensation operation may be performed for the fourth pulse voltage Vp4′ based on the positive boost voltage and the process compensation voltage.

FIG. 12 shows that the pulse voltage Vp is output as the first to fourth pulse voltages Vp1′ to Vp4′ with the different voltage levels. However, the pulse voltage Vp may be output as two voltage levels based on the operation of the plasma processing apparatus 1′.

Referring to FIG. 14 together, a wafer voltage Vwafer′ may be changed by the bias voltage Vbias′. The time point t12, which is the rise edge time point of the bias voltage Vbias′, may be a rise edge of the wafer voltage Vwafer′. At the time point t12, through the positive boost voltage of the compensation voltage, the delay caused by the parasitic resistance Rs and parasitic coil Ls of FIG. 2 may be prevented or reduced, and performance of a rise edge transition time T_re of the wafer voltage Vwafer′ may be improved.

The wafer voltage Vwafer′ may be maintained at the first voltage V1′ without a droop phenomenon from the time point t12, which is the etching period Te′, to the time point t14. Likewise, the wafer voltage Vwafer′ may maintain the second voltage V2′ without the droop phenomenon from the time point t16 to the time point t18, which is the etching period Te′. The compensation operation may be performed during the etching period Te′, based on the process compensation voltage of the disclosure, thus improving the compensation operation performance for the non-linear ion current I_ion of FIG. 2.

The time point t14, which is the drop edge time point of the bias voltage Vbias′, may be a drop edge of the wafer voltage Vwafer′. At the time point t14, through the negative boost voltage of the compensation voltage Vcomp, the delay caused by the parasitic resistance Rs and parasitic coil Ls of FIG. 2 may be prevented or reduced, and performance of a drop edge transition time T_fe of the wafer voltage Vwafer′ may be improved.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the example embodiments of the disclosure have been described in detail hereinabove, the scope of the disclosure is not limited thereto, and may include several modifications and alterations made by those skilled in the art using a basic concept of the disclosure as defined in the claims.

What is claimed is:

1. A plasma processing apparatus comprising:
a chamber where a wafer is configured to be mounted;
a source power configured to provide a source voltage to generate a plasma in the chamber;
a multi-level pulse circuit configured to generate a wafer voltage to accelerate ions in the plasma, and generate a pulse signal including sequentially outputting a first pulse voltage, a second pulse voltage having a level lower than the first pulse voltage, and a third pulse voltage different from the first and second pulse voltages and having a level higher than the second pulse voltage; and
an arbitrary voltage compensation circuit configured to provide a compensation voltage non-linearly changed to at least one of the first to third pulse voltages.

2. The apparatus of claim 1, wherein
the multi-level pulse circuit includes
a pulse voltage generation circuit configured to generate the a plurality of pulse voltages including the first to third pulse voltages and including a plurality of voltage modules, and
control logic configured to control the pulse voltage generation circuit based on a plurality of control signals corresponding to the plurality of voltage modules.

3. The apparatus of claim 2, wherein
the plurality of voltage modules include a first variable voltage module configured to provide a first variable voltage, a second variable voltage module configured to provide a second variable voltage, a first fixed voltage module configured to provide a first fixed voltage, and a second fixed voltage module configured to provide a second fixed voltage, and
the first and second variable voltage modules and the first and second fixed voltage modules are connected in series with each other and configured to to output the pulse voltages.

4. The apparatus of claim 3, wherein
the first variable voltage module includes a first voltage source configured to generate the first variable voltage, a first switch connected in series with the first voltage source, and a first diode connected in parallel with the first voltage source and the first switch,
the second variable voltage module includes a second voltage source configured to generate the second variable voltage, a second switch connected in series with the second voltage source, and a second diode connected in parallel with the second voltage source and the second switch,
the first fixed voltage module includes a third voltage source configured to generate the first fixed voltage, a third switch connected in series with the third voltage source, and a third diode connected in parallel with the third voltage source and the third switch, and
the second fixed voltage module includes a fourth voltage source configured to generate the second fixed voltage, a fourth switch connected in series with the fourth voltage source, and a fourth diode connected in parallel with the fourth voltage source and the fourth switch.

5. The apparatus of claim 1, wherein
the arbitrary voltage compensation circuit is configured to store waveform information corresponding to the compensation voltage in a form of a look-up table.

6. The apparatus of claim 5, wherein
the arbitrary voltage compensation circuit is configured to change at least a portion of the compensation voltage to a quadratic function or an exponential function.

7. The apparatus of claim 1, wherein
the multi-level pulse circuit is configured to output the first pulse voltage during a first process performance period, and outputs the third pulse voltage during a second process performance period after the first process performance period.

8. The apparatus of claim 7, wherein
The arbitrary voltage compensation circuit is configured to provide a process compensation voltage corresponding to the compensation voltages in the first process performance period and the second process performance period.

9. The apparatus of claim 8, wherein
the process compensation voltage is non-linearly changed in response to accumulation of the ions in the plasma.

10. A plasma processing apparatus comprising:
a chamber where a wafer is configured to be mounted;
a source power configured to provide a source voltage to generate a plasma in the chamber;
a multi-level pulse circuit configured to generate a wafer voltage to accelerate ions in the plasma, and generate a pulse signal including a rise edge where the voltage rises and a drop edge where the voltage drops, during a predetermined period; and
an arbitrary voltage compensation circuit configured to provide a first boost voltage at the rise edge based on a boost period based on the predetermined period, provide a second boost voltage at the drop edge based on the boost period, and provide a process compensation voltage to the pulse signal after providing at least one of the first and second boost voltages.

11. The apparatus of claim 10, wherein
the first boost voltage is a positive boost voltage whose voltage rises at the rise edge, and
the second boost voltage is a negative boost voltage whose voltage drops at the drop edge.

12. The apparatus of claim 11, wherein
at the rise edge, a ratio of a magnitude of the first boost voltage and a voltage rise range of the pulse signal is in a range of 0.1 to 0.3.

13. The apparatus of claim 10, wherein
a time ratio of the boost period and the predetermined period is in a range of 0.05 to 0.15.

14. The apparatus of claim 10, wherein
the arbitrary voltage compensation circuit is configured to provide the process compensation voltage after providing the second boost voltage.

15. The apparatus of claim 10, wherein
the arbitrary voltage compensation circuit is configured to provide the process compensation voltage between the provision of the first boost voltage and the provision of the second boost voltage.

16. The apparatus of claim 10, wherein
the arbitrary voltage compensation circuit includes
a signal generator configured to output a non-linear signal based on the predetermined period,
an amplifier configured to amplify the non-linear signal to generate a preliminary compensation voltage, and
a reactive circuit configured to generate the compensation voltage by adjusting a phase of the preliminary compensation voltage.

17. The apparatus of claim 16, wherein
the signal generator is configured to store a look-up table including a plurality of signal waveforms each corresponding to the compensation voltage, and outputs the non-linear signal based on the look-up table.

18. The apparatus of claim 16, wherein
the reactive circuit is a transformer coil.

19. A plasma processing apparatus comprising:
a chamber where a wafer is configured to be mounted;
a gas injection unit configured to inject a process gas into the wafer, and including an upper electrode that is grounded;
a supporter configured to support the wafer under the gas injection unit, and including a lower electrode;
a source power electrically connected to the lower electrode, and configured to provide a source voltage to convert the process gas into plasma to generate plasma ions; and
a bias power electrically connected to the lower electrode, configured to generate a plurality of pulse voltages including sequentially outputting a first pulse voltage, a second pulse voltage lower than the first pulse voltage, and a third pulse voltage different from the first and second pulse voltages and higher than the second pulse voltage, and perform a non-linear compensation operation for the second pulse voltages.

20. The apparatus of claim 19, wherein
the bias power is configured to generate a bias voltage based on the pulse voltage and the compensation operation, and
the bias voltage is generated by performing the non-linear compensation operation for the second pulse voltage based on a negative boost voltage during an etching period in which the second pulse voltage is generated.
